(19) United States
(12) Patent Application Publication
(10) Pub. No.: US 2005/0022735 A1
(43) Pub. Date: Feb. 3, 2005

(54) Delivery system for PECVD powered electrode

(75) Inventors: Eric Michael Breitung, Albany, NY (US); George Theodore Dalakos, Niskayuna, NY (US); Peter Joseph Codella, Niskayuna, NY (US); Manisha Tinani-Mendleson, Albany, NY (US)

Correspondence Address: General Electric Company;CRD Patent Docket Rm 4A59, P.O. Box 8, Bldg. K-1, Schenectady, NY, 12301, US

(73) Assignee: General Electric Company

(21) Appl. No.: 10/630,139

(22) Filed: Jul. 31, 2003

(51) Int. Cl. C23C 16/00; C23F 1/00

(52) U.S. Cl. 118/715

(57) ABSTRACT

Gas delivery devices for PECVD systems and methods for using such systems are described. The delivery device goes directly through the powered electrode and thereby bypasses components of the PECVD systems used to support that electrode. The delivery device contains a coupling device between the powered electrode of the PECVD reactor and the gas inlet line. The gas inlet line is electrically and thermally isolated from the powered electrode and is sealed to maintain the vacuum integrity of the PECVD reactor through the use of a coupling device. Thus, gases from the heated gas lines can be routed directly through the powered electrode and fed into the reactor via the showerhead without having a cold area between the showerhead and gas inlet line.

### BACKGROUND OF THE INVENTION

This invention generally relates to thin film deposition and etching apparatus and methods for using the same. More particularly, this invention relates to chemical vapor deposition apparatus and methods for using the same. Even more particularly, this invention relates to gas delivery systems for plasma enhanced chemical vapor deposition apparatus and methods for using such systems.

There are numerous methods for depositing and etching films on substrates. One method for film deposition is by chemical vapor deposition (CVD). In CVD, the materials that are to be deposited as the films are formed as a result of a chemical reaction between gaseous reactants at elevated temperatures in the vicinity of the substrate. The product of the reaction is then deposited on the surface of the substrate. CVD can be used to deposit films of semiconducting materials (crystalline and non-crystalline), insulating materials, as well as metals.

There are variants of CVD processes, including Atmospheric Pressure CVD (APCVD), Low Pressure CVD (LPCVD) and Plasma Enhanced CVD (PECVD). In PECVD, the materials to be deposited are generated in a gas-phase plasma located in fairly close proximity to the substrate. Thus, when using the same source gases as other CVD processes, PECVD can operate at a lower temperature than such other CVD where a higher temperature is needed to break the chemical bonds of the gaseous reactants and to generate the species needed to form the film.

As shown in FIG. 1, a typical PECVD apparatus 10 includes a PECVD reactor chamber 12 and a powered electrode 16. The powered electrode 16 is connected to a gas delivery system 60 to allow the introduction of gases 64 and 72. A gas mixture 28 flows through the powered electrode 16 to its center and are then vented into an open space above the showerhead 15. The showerhead 15 allows gases to pass into the interior region of the chamber 12. The showerhead 15 also serves as a gas distribution mechanism that provides a substantially uniform gas flow to the interior of the chamber 12.

Also shown in FIG. 1, the showerhead 15 is part of the powered electrode 16 and carries the same voltage as the powered electrode 16. Special precautions are often necessary, however, in the powered electrode 16 to keep the potentials electrically isolated from the rest of the PECVD apparatus 10 and the gas lines 42 and 77. The powered electrode 16 is connected to an external RF power source 36. In addition, the powered electrode 16 usually contains some mechanism (not shown) for heating the gas mixture 28, such as water circulation coils. Typically, the showerhead 15 is composed of aluminum or an aluminum alloy with small holes 17 extending from a top surface 24 of the showerhead 15 to a bottom surface 26. An electrical insulator 80 is provided to isolate the powered electrode 16 from other portions of the PECVD apparatus 10. In addition, O-rings (or other sealing devices) 82 are provided between the powered electrode 16 and the sidewalls 32 of the chamber 12 to isolate the powered electrode 16 and assist in maintaining vacuum or near-vacuum conditions in the chamber 12.

A lower (powered or un-powered) electrode 18 in the form of a plate supports substrate 38 and extends within the chamber 12 parallel to the powered electrode 16.

The lower electrode 18 is often formed of aluminum and coated with a layer of aluminum oxide. Embedded within the lower electrode 18 is one or more heating elements (not shown) to control its temperature. The lower electrode 18 is connected to ground and is mounted on shaft 20 that extends vertically through a bottom wall 22 of the chamber 12. The shaft 20 can move vertically, e.g., toward and away from the powered electrode 16.

Gas outlet 30 extends through a wall 22 of the chamber 12 and is connected to a pump (not shown) for evacuating the chamber 12. There can be other gas outlets 30 that can be located in any wall 22, 32 of the chamber 12. A gas inlet line 42 is connected to reservoirs of various gases, such as, for example, primary gas supply 72 and secondary gas supply 64. The flow of the primary gas supply 72 and the secondary gas supply 64 are controlled by a valve/control mechanism 73 and 70, respectively. The gases supplies 72 and 64 are then mixed in mixer 66 to obtain a homogenous gas mixture. The gas mixture flows through conduit 77, through the gas inlet pipe 42 into the powered electrode 16, and then through the showerhead 15 into the chamber 12. A valve/flow mechanism 79 controls the flow of the gas mixture 28.

As further shown in FIG. 1, the gas mixture 28 enters the chamber 12 via the gas inlet line 42 that is often composed of aluminum and/or a ceramic material. The gas mixture 28 flows through gas inlet line 42 into chamber 12 around a first corner 54, around a second corner 56, and then to the powered electrode 16 and the showerhead 15. Such configurations for delivering the gas mixture 28 to the chamber 12 routes the gas mixture 28 through the unheated areas of gas inlet line 42. At these unheated areas, the gas mixture 28 can condense easily and clog the gas inlet line 42 especially at corners 54 and 56. Typically, elevated heating of the gas inlet line 42 is not performed because the materials used to structurally hold the powered electrode 16 have low melting points. In addition, the gas inlet line 42 is imbedded in a thick block of aluminum which is difficult to heat. As such, the gas inlet line 42 is usually maintained at relatively low temperatures.

Other methods have been used to compensate for these problems mentioned above. For example, one such method dilutes the gas mixture 28 using carrier gases, such as, argon, nitrogen, helium, hydrogen, or oxygen, etc. The diluted gas mixture is able to flow through conventional delivery systems without significant heating. However, this method decreases the efficiency and increases the cost of the CVD operation.

### BRIEF SUMMARY OF THE INVENTION

The invention relates to gas delivery systems for PECVD reactors and methods for using such systems. The delivery system goes directly through the powered electrode and thereby bypasses components of the PECVD reactor used to support that electrode. The delivery system contains a coupling device between the powered electrode of the PECVD reactor and the gas inlet line. The gas inlet line is electrically and thermally isolated from the powered electrode and is sealed to maintain the vacuum integrity of the PECVD reactor through the use of a coupling device. Thus, gases from the heated gas lines can be routed directly through the powered electrode and fed into the reactor via the showerhead without having a cold area between the showerhead and gas inlet line.

The invention includes a delivery device for a thin film deposition or etching apparatus containing a heated gas inlet line for delivering a gas to a powered electrode of the apparatus, the gas inlet line maintained under a vacuum and a coupling device located between the powered electrode and the gas inlet line, the coupling device comprising insulation portion. The invention also includes a system for delivering a gas to a thin film deposition or etching apparatus with the system containing a heated gas inlet line maintained under a vacuum and a coupling device located between a powered electrode of the apparatus and the gas inlet line wherein the coupling device comprises the thermal and electrical insulation portion. The invention further includes a PECVD apparatus containing a delivery system with the system containing a heated gas inlet line maintained under a vacuum and a coupling device located between the powered electrode of the PECVD apparatus and the gas inlet line, the coupling device comprising insulation portion and flange for helping maintain the gas inlet line under a vacuum.

The invention also includes a method for supplying a gas to a thin film deposition or etching apparatus by providing a delivery system containing a heated gas inlet line maintained under a vacuum, and containing a coupling device located between a powered electrode of the apparatus and the gas inlet line, wherein the coupling device comprises electrical and thermal insulation portion, and then providing a gas to the delivery system. The invention also includes a method for supplying a gas to a PECVD apparatus by providing a gas, flowing the gas through a heated gas inlet line, flowing the gas through a coupling device containing insulation device, and flowing the gas to a powered electrode of the PECVD apparatus. The invention further includes a method for depositing a film on a substrate by providing a gas, flowing the gas through a heated gas inlet line, flowing the gas through a coupling device containing insulation device, and flowing the gas to a deposition apparatus where the gas is converted to a plasma and then deposited as a film on a substrate contained within the deposition apparatus. The invention still further includes a method for etching a film from a substrate by providing a gas, flowing the gas through a heated gas inlet line, flowing the gas through a coupling device containing insulation device, and flowing the gas to an etching apparatus where the gas is converted to a plasma and then used to remove a portion of a film on a substrate contained within the etching apparatus.

### BRIEF DESCRIPTION OF THE DRAWINGS

FIGS. 1-3 are views of one aspect of the gas delivery systems and methods of using such systems according to the invention, in which:

FIG. 1 is a cut-away view of a conventional, prior art PECVD apparatus;

FIG. 2 is a cut-away view of one exemplary embodiment of a PECVD delivery system; and

FIG. 3 is another cut-away view of another exemplary embodiment of a PECVD delivery system.

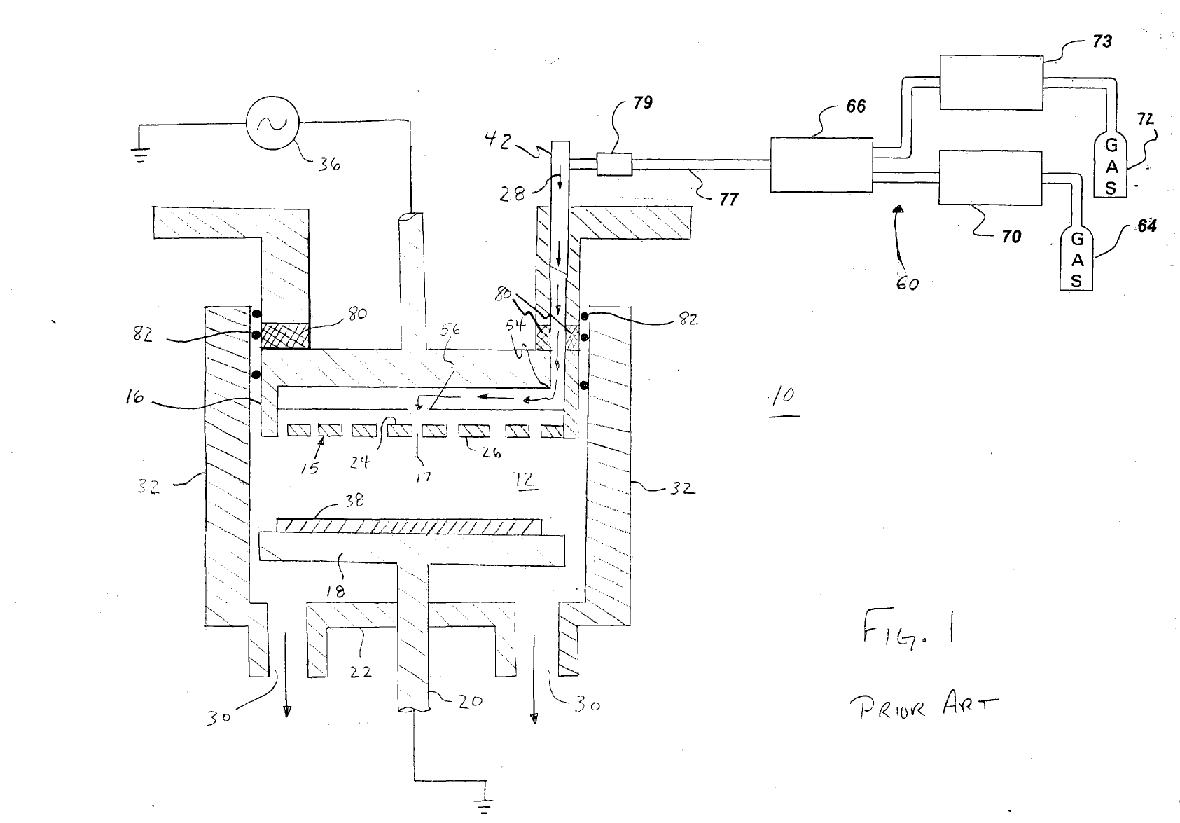

FIGS. 1-3 presented in conjunction with this description depicts only particular-rather than complete-portions of the gas delivery systems and methods of using such systems in one aspect of the invention. Together with the following description, the Figures demonstrate and explain the principles of the invention.

### DETAILED DESCRIPTION OF THE INVENTION

The following description presents specific details in order to provide a thorough understanding of the invention. The one skilled in the art, however, would understand that the invention can be practiced without employing these specific details. Indeed, the present invention can be practiced by modifying the illustrated system and method and can be used in conjunction with apparatus and techniques conventionally used in the industry. For example, the invention is described with reference to parallel-plate PECVD reactors, but could be used for other types of PECVD, and even other CVD apparatus. In fact, the invention could be used in combination with other thin film deposition (and etching) apparatus.

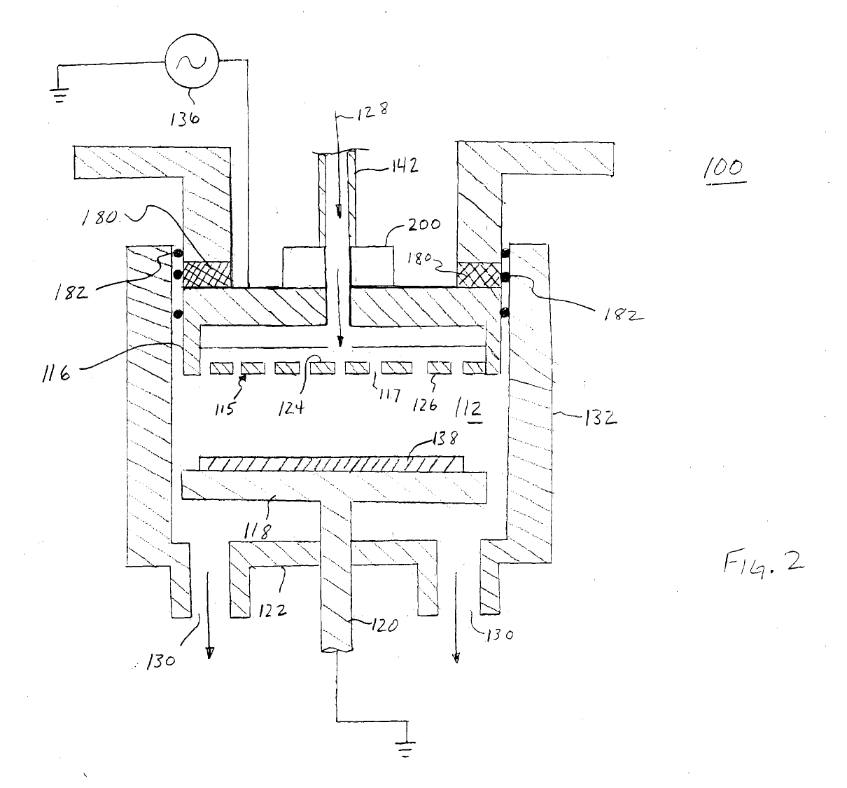

As shown in FIG. 2, one exemplary embodiment of the invention generally pertains to a system 100 for delivering gases into a PECVD reactor chamber 112. The system 100 supplies inlet gases directly into the powered electrode 116 and allows heating of the entire gas inlet line 142 including in areas near the powered electrode 116. The system 100 is able to perform these functions while also maintaining the vacuum integrity of the chamber 112.

It should be appreciated that any gas delivery system, including the embodiment shown in FIG. 1, can be used in the invention, including the system 100 depicted in FIG. 2. As shown in FIG. 2, the 100 includes a PECVD reactor chamber 112 and a powered electrode 116. The powered electrode 116 can similarly be connected to a gas delivery system 60 (FIG. 1) to allow the introduction of gases 64 (FIG. 1) and 72 (FIG. 1). In FIG. 2, the gas mixture 128 flows directly through the powered electrode 116 and directly into an open space above the showerhead 115. The showerhead 115 allows gases to pass into the interior region of the chamber 112. The showerhead 115 also serves as a gas distribution mechanism that provides a substantially uniform gas flow to the interior of the chamber 112.

As further shown in FIG. 2, the showerhead 115 is part of the powered electrode 116 that is connected to an external RF power source 136. In addition, the powered electrode 116 can also contains some mechanism (not shown) for heating the gas mixture 128, such as water circulation coils and other heating devices. In one embodiment, the showerhead 15 is composed of aluminum or an aluminum alloy. Further, the showerhead 115 contains small holes 117 extending from a top surface 124 of the showerhead 115 to a bottom surface 126. An electrical insulator 180 is provided to isolate the powered electrode 116 from other portions of the PECVD apparatus 100. In addition, o-rings (or other sealing devices) 182 are provided between the powered electrode 116 and the sidewalls 132 of the chamber 112 to isolate the powered electrode 116 and assist in maintaining vacuum or near-vacuum conditions in the chamber 112.

A lower electrode 118 supports substrate 138 and extends within the chamber 112 parallel to the powered electrode 116. In another embodiment, the lower electrode 118 can comprise a powered or non-powered electrode. In even another embodiment, the lower electrode can comprise a plate structure. However, it should be appreciated that the lower electrode 118 can comprise other configurations. In another embodiment, the lower electrode 18 is comprised of aluminum and coated with a layer of aluminum oxide. In yet another embodiment, the lower electrode 118 can be embedded with one or more heating elements (not shown) to control the temperature of the lower electrode 118. Further, when unpowered, the lower electrode 118 is connected to ground and is mounted on shaft 120 that extends vertically through a bottom wall 122 of the chamber 112. It should be appreciated that, in one embodiment, the shaft 120 can move vertically, e.g., toward and/or away from the powered electrode 116.

Gas outlet 130 extends through a wall 122 of the chamber 112 and is connected to a pump (not shown) for evacuating the chamber 112. In another embodiment, other gas outlets 130 and these gas outlets can be located in any wall 122, 132 of the chamber 112.

In one aspect as shown in FIG. 2, the gas mixture 128 is inserted directly into the powered electrode 116 and showerhead 115 via gas inlet line 142. By configuring the gas inlet line 142 into the powered electrode 116 using coupling 200, the accumulation of the gas mixture 128 on the walls of the gas inlet line 142 is reduced or eliminated. It should be appreciated that, in one embodiment, gas inlet line 142 can be heated using external or imbedded heating mechanisms (not shown).

Using the coupling 200, the gas mixture 128 is directly supplied into the powered electrode 116. In one embodiment, the coupling 200 is connected so that the gas inlet line 142 is electrically and thermally isolated from the powered electrode 116 and so that the gas inlet line 142 is capable of being maintained under vacuum pressure or near vacuum pressure.

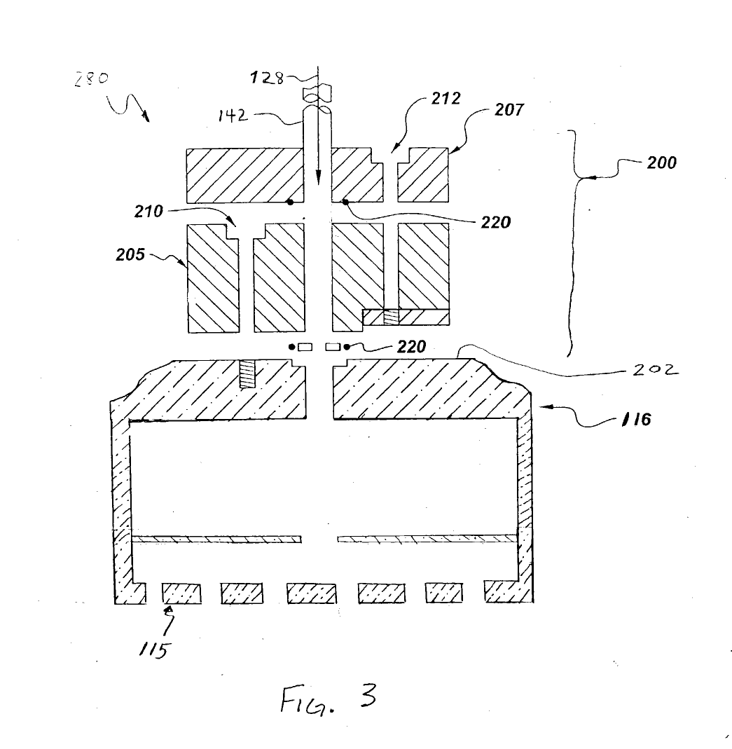

As shown in FIG. 3, the coupling 200 is comprised in a delivery device 280 of a PECVD apparatus 100 (FIG. 2). In one embodiment, the coupling 200 is installed on the upper side 202 of powered electrode 116 in a PECVD apparatus 100 (FIG. 2) to facilitate the gas mixture 128 being supplied directly provided to powered electrode 116. The coupling device 200 connects and/or couples the gas inlet line 142 with the powered electrode 116 positioned proximate to shower head 115, while as the same time electrically and thermally isolating the gas inlet line 142 from the powered electrode 116 and sealing the gas inlet line 142 under vacuum conditions. In one embodiment, the coupling device 200 operates in this manner by using an electrical and thermal insulation portion 205 and incorporating a flange 207 for maintaining a vacuum-tight or near-vacuum-tight seal.

The insulation portion 205 electrically isolates the gas inlet line 142 from the upper surface 202 of the powered electrode 116. The insulation portion 205 also thermally isolates the gas inlet line 142 from the upper surface 202 of the powered electrode 116. It should be appreciated that the insulation portion 205 can comprise any suitable shape and/or be composed of made a material that achieves the objectives discussed herein. Consistent with these insulation functions, the insulation portion 205 can be composed of electrical and thermal insulating materials, such as plastics or ceramic materials. In one embodiment, the insulation portion 205 is made of a ceramic material, such as MACOR™.

In one embodiment, the insulation portion 205 is shaped similar to flange 207. For example, the flange 207 can comprise a vacuum flange, and the insulation portion 205 can comprise an isolation ring as shown in FIG. 3. In this embodiment, the insulation portion 205 is configured to connect flush with flange 207 as well as the upper surface 202 of the powered electrode 116.

The flange 207 serves to connect the insulation portion 205 with gas inlet line 142 while maintaining the existing vacuum conditions. It should be appreciated, in one embodiment, that gas inlet line 142 can be connected to or integrally formed as a part of flange 207. It should be further appreciated that the flange 207 can be any suitable shape and can be composed of any material to achieve the objectives discussed herein. As discussed above, in one embodiment, the flange 207 comprises a vacuum flange.

As shown in FIG. 3, the coupling device 200 is connected to both the gas inlet line 142 and the upper surface 202 of the powered electrode 116 in any suitable manner. As well, the two components of the coupling device 200 (insulation portion 205 and flange 207) are interconnected in any suitable manner. One embodiment of such a connection is shown in FIG. 3 where a plurality of fastening bolts (not shown) secure the insulation portion 205 to the upper surface 202 though a corresponding plurality of holes 210. In one embodiment, the holes 210 are countersunk for bolts (not shown) that are used to attach the coupling device 200 to the top surface 202 of the powered electrode 116, thereby avoiding contact of the fastening bolt heads with the flange 207. In another embodiment, the bolts (not shown) and corresponding holes 210 are offset by about 120 degrees to fasten the coupling device 200 to the upper surface 202 of the powered electrode 116. It should be appreciated that with more (or less) holes 210 and corresponding bolts, the offset angle may be different than about 120 degrees.

As further shown in FIG. 3, the flange 207 is fastened to insulation portion 205 via fastening bolts (not shown) though a corresponding plurality of holes 212. The bolts can be configured to avoid electrically contacting the powered electrode 116. In one embodiment, the holes 212 have channels that allow for clearance between the bolts and the powered electrode 116. In another embodiment, the flange 207 and the insulation portion 205 comprise three bolts and three corresponding holes 212 that are each offset from one another by about 120 degrees. Further, the bolts and corresponding holes 212 are, in turn, offset by about 60 degrees from the previously set of three fastening bolts and holes 210 described above in relation to the insulation portion 205 and the upper side 202 of the powered electrode 116. It should be appreciated that the offset angle may be different with more (or less) holes 212 and corresponding bolts.

It should further be appreciated that the coupling device 200 can contain additional component that assist in operation as described above. For example, in one embodiment, the coupling device 200 can comprise additional components to assist in the connection of the gas inlet line 142 to the powered electrode 116. In another embodiment, the flange 207 and the insulation portion 205 can comprise additional components to assist in their interconnection. In yet another embodiment, the coupling device 200 can contain internal sealing portions disposed between the various components, for example, O-rings 220 (and, if necessary, corresponding grooves for the O-rings 220) can be used form a tight seal.

The coupling device 200 can be used in any PECVD apparatus known in the art and may be extended to those systems developed in the future. In the embodiments described herein, the coupling device 200 is used in combination with a parallel-plate PECVD reactor, but the coupling device 200 could be used in other CVD reactors (e.g., LPCVD reactors). In yet another embodiment, the coupling device 200 can be used in a sputtering apparatus. In addition, the coupling device 200 can be used in any thin film deposition or etching apparatus where the gas needs to be directly inserted into the apparatus and the gas inlet line needs to be electrically and thermally isolated from the remainder of the apparatus.

In operation, the coupling device 200 is disposed in the PECVD apparatus 100 between the gas inlet line 142 and the powered electrode 116. In one embodiment, when the PECVD apparatus 100 is operated, the coupling device 200 allows the entire gas line (including the gas inlet line 142) to remain heated. In embodiments where aluminum is used, the inlet gas line 142 can be operated at a temperature ranging from about 25 to about 110 degrees Celsius. In another embodiment, the inlet gas line 142 can be operated at a temperature ranging from about 25 to about 90 degrees Celsius. It should be appreciated that other operating temperatures could be used where other materials are used, e.g., the operating temperature could range up to about 400 degree Celsius.

In another embodiment of operation, a film is deposited on a substrate 138 by providing a gas mixture 128. The gas mixture 128 flows through a heated gas inlet line 128, and the coupling device 200. In this embodiment, the gas mixture 128 is provided into chamber 112 where the gas mixture 128 is converted to a plasma and then deposited as a film on the substrate 138 contained within the chamber 112. In even another embodiment, a film can be etched from the substrate 138 by providing the gas mixture 128 via the heated gas inlet line 142 through the coupling device 200. When the gas mixture 128 is provided in the chamber 112, the gas mixture 112 is converted to a plasma and then used to remove a portion of a film on a substrate 138 contained within the etching apparatus 100.

By using the coupling device 200, a PECVD apparatus 100 can have improved performance with relation to conventional systems. For example, one measurement of such performance is less clogging in the channel of the inlet gas line 142. Using the coupling device 200, up to about 95% (and even to about 100%) less gas mixture residue is left on the walls of the gas inlet line 142.

The following non-limiting example illustrates the invention.

### EXAMPLE

A parallel-plate PECVD apparatus 100 including coupling device 200 similar to FIGS. 2 and 3 was constructed. The PECVD apparatus 100 was used to feed TaF₅ to the PECVD reactor chamber under the following conditions: 300 mT, PE mode, 300 sccm Argon, 5 sccm TaF₅, 200 sccm Hydrogen, 200 sccm Oxygen, and 150 Watts. The gas lines leading up to the reactor were kept at 160 degrees Celsius, and the reactor electrodes were operated at 100 degrees C. The PECVD operation failed after 30 minutes due to extreme clogging of TaF₅ at the juncture between the gas line and the chamber.

A PECVD apparatus similar to FIGS. 2 and 3 was then constructed for the PECVD reactor. The PECVD reactor was then operated under the following conditions: 300 mT, PE mode, 300 sccm Argon, 5 sccm TaF₅, 200 sccm Hydrogen, 200 sccm Oxygen, and 150 Watts. The gas line leading up to the reactor was kept at 160 degrees Celsius, the powered electrode was heated to 145 degrees Celsius, and the lower electrode was heated to 275 degrees C. The PECVD reactor was operated for 30 minutes with negligible clogging of the gas line.

Having described these aspects of the invention, it is understood that the invention defined by the appended claims is not to be limited by particular details set forth in the above description, as many apparent variations thereof are possible without departing from the spirit or scope thereof.

1. A delivery device for a thin film deposition or etching apparatus, comprising:
a heated gas inlet line for delivering a gas to a powered electrode of the apparatus, the gas inlet line maintained under a vacuum; and
a coupling device located between the powered electrode and the gas inlet line, the coupling device comprising insulation portion.

2. The device of claim 1, wherein the gas inlet line is directly connected to the coupling device.

3. The device of claim 2, wherein the coupling device is directly connected to the powered electrode.

4. The device of claim 1, wherein the thin film deposition or etching apparatus comprises a PECVD apparatus.

5. The device of claim 1, wherein the insulation portion is both thermally and electrically insulating.

6. The device of claim 1, wherein the insulation portion comprises a plastic or a ceramic material.

7. The device of claim 3, wherein the coupling device further comprises a flange for maintaining the gas inlet line under a vacuum.

8. The device of claim 7, wherein the flange is connected to the gas inlet line, the insulation portion is connected to the powered electrode, and the insulation portion and flange are connected to each other.

9. A delivery device for delivering a gas to a thin film deposition or etching apparatus, the system comprising:
a heated gas inlet line maintained under a vacuum; and
a coupling device located between a powered electrode of the apparatus and the gas inlet line, the coupling device comprising thermal and electrical insulation portion.

10. The device of claim 9, wherein the gas inlet line is directly connected to the coupling device.

11. The device of claim 10, wherein the coupling device is directly connected to the powered electrode.

12. The device of claim 9, wherein the electrical insulation portion comprises a plastic or a ceramic material.

13. The device of claim 11, wherein the coupling device further comprises a flange for maintaining the gas inlet line under a vacuum.

14. The device of claim 13, wherein the flange is connected to the gas inlet line, the insulation portion is connected to the powered electrode, and the insulation portion and flange are connected to each other.

15. A PECVD apparatus containing a delivery system, the system comprising:
a heated gas inlet line maintained under a vacuum; and
a coupling device located between a powered electrode of the PECVD apparatus and the gas inlet line, the coupling device comprising insulation portion and flange device for maintaining the gas inlet line under a vacuum.

16. The device of claim 15, wherein the gas inlet line is directly connected to the coupling device and the coupling device is directly connected to the powered electrode.

17. The device of claim 15, wherein the insulation portion is both thermally and electrically insulating.

18. The device of claim 16, wherein the flange is connected to the gas inlet line, the insulation portion is connected to the powered electrode, and the insulation portion and flange are connected to each other.

19. A method for supplying a gas to a thin film deposition or etching apparatus, comprising:
providing a delivery system containing a heated gas inlet line maintained under a vacuum, and containing a coupling device located between a powered electrode of the apparatus and the gas inlet line, wherein the coupling device comprises electrical and thermal insulation portion; and
providing a gas to the delivery system.

20. The method of claim 19, wherein the gas inlet line is directly connected to the coupling device and the coupling device is directly connected to the powered electrode.

21. The device of claim 20, wherein the coupling device further comprises a flange for maintaining the gas inlet line under a vacuum.

22. The device of claim 21, wherein the flange is connected to the gas inlet line, the insulation portion is connected to the powered electrode, and the insulation portion and flange are connected to each other.

23. A method for supplying a gas to a PECVD apparatus, comprising:
providing a gas;
flowing the gas through a heated gas inlet line;
flowing the gas through a coupling device containing insulation portion; and
flowing the gas to a powered electrode of the PECVD apparatus.

24. The method of claim 23, wherein the gas flows directly from the gas inlet line to the coupling device.

25. The method of claim 24, wherein the gas flows directly from the coupling device to the powered electrode.

26. The method of claim 23, wherein the insulation portion is both thermally and electrically insulating.

27. The method of claim 26, wherein the insulation portion comprises a plastic or a ceramic material.

28. A method for depositing a film on a substrate, comprising:
providing a gas;
flowing the gas through a heated gas inlet line;
flowing the gas through a coupling device containing an insulation portion; and
flowing the gas to a deposition apparatus where the gas is converted to a plasma and then deposited as a film on a substrate contained within the deposition apparatus.

29 The method of claim 28, wherein the gas flows directly from the gas inlet line to the coupling device and then from the coupling device to a powered electrode of the deposition apparatus.

30. A method for etching a film from a substrate, comprising:
providing a gas;
flowing the gas through a heated gas inlet line;
flowing the gas through a coupling device containing insulation portion; and
flowing the gas to an etching apparatus where the gas is converted to a plasma and then used to remove a portion of a film on a substrate contained within the etching apparatus.

31. The method of claim 30, wherein the gas flows directly from the gas inlet line to the coupling device and then from the coupling device to a powered electrode of the etching apparatus.
